(19) United States
(12) Patent Application Publication
(10) Pub. No.: US 2012/0241850 A1
(43) Pub. Date: Sep. 27, 2012

(54) SEMICONDUCTOR DEVICE

(75) Inventor: Yusuke KAWAGUCHI, Kanagawa-ken (JP)

(73) Assignee: Kabushiki Kaisha Toshiba, Tokyo (JP)

(21) Appl. No.: 13/239,106

(22) Filed: Sep. 21, 2011

(30) Foreign Application Priority Data
Mar. 25, 2011 (JP) 2011-067907

(51) Int. Cl. H01L 29/78

(52) U.S. Cl. 257/330; 257/E29.262

(57) ABSTRACT

A semiconductor device includes a drain layer, a drift region provided from a surface inside of the drain layer, a base region provided from a surface inside of the drift region, a source region provided in a trench form from a surface inside of the base region, and a gate electrode provided via a gate insulating film in a first trench. The gate electrode is extended from a part of the source region to a part of the drift region in a direction approximately parallel to a rear face of the drain layer. The semiconductor device further includes a first resistive body layer provided via a first insulating film in at least one of second trenches provided from a surface inside of the drain layer.

### CROSS-REFERENCE TO RELATED APPLICATIONS

This application is based upon and claims the benefit of priority from the prior Japanese Patent Application No. 2011-067907, filed on Mar. 25, 2011; the entire contents of which are incorporated herein by reference.

### FIELD

Embodiments described herein relate generally to a semiconductor device.

### BACKGROUND

Power MOSFETs (Metal Oxide Semiconductor Field Effect Transistor) are used, in addition to markets of switching power sources of high current and high breakdown voltage, in markets of energy saving switching for mobile communication devices etc. including notebook-sized personal computers. Since the power MOSFET is used as a power management circuit, a safety circuit of lithium ion batteries etc., low voltage driving and a low ON-resistance are promoted.

In order to reduce the ON-resistance, there is a three-dimensional type MOSFET in which a channel region is formed not only on the major surface of a semiconductor substrate but also in the vertical direction of the semiconductor substrate. In the three-dimensional type MOSFET, in a direction approximately perpendicular to the major surface of the semiconductor substrate, each of a source region, a base region, and a drain region is extended, and, furthermore, a trench type gate electrode is provided. In such structure, the channel region is formed in a direction approximately parallel to the major surface of the semiconductor substrate, and the channel region is also formed in a direction approximately perpendicular to the major surface of the semiconductor substrate. Consequently, in the three-dimensional type MOSFET, a channel density is remarkably improved and the low ON-resistance is realized.

However, when the MOSFET is subjected to high-speed switching, the voltage (Vds) between a source electrode and a drain electrode may repeat overshoot and undershoot to generate ringing of the vibrating Vds. Such ringing of Vds may acts as a noise source and is desirably suppressed as much as possible.

### BRIEF DESCRIPTION OF THE DRAWINGS

FIG. 1 is a perspective schematic view of the semiconductor device according to a first embodiment;

FIGS. 2A and 2B are schematic views of a part surrounded by a region 90 in FIG. 1;

FIG. 3 is an equivalent circuit view of the semiconductor device according to the first embodiment;

FIGS. 4A to 6B are perspective schematic views for explaining the manufacturing process of the semiconductor device according to the first embodiment;

FIGS. 7A and 7B are schematic views of the semiconductor device according to the reference example;

FIGS. 8A and 8B are perspective schematic views for explaining a first modified example of the semiconductor device according to the first embodiment;

FIGS. 9A and 9B are perspective schematic views for explaining a second modified example of the semiconductor device according to the first embodiment;

FIG. 10 is a perspective schematic view of the semiconductor device according to a second embodiment; and

FIG. 11 is a perspective schematic view of the semiconductor device according to a third embodiment.

### DETAILED DESCRIPTION

In general, according to one embodiment, a semiconductor device is disclosed. The semiconductor device can include a drain layer of a first conductivity type. The semiconductor device can include a drift region of the first conductivity type provided from a surface to an inside of the drain layer. The drift region is in the form of a trench. The semiconductor device can include a base region of a second conductivity type provided from a surface to an inside of the drift region. The base region is in the form of a trench. The semiconductor device can include a source region of the first conductivity type provided in a trench form from a surface to an inside of the base region. The source region is in the form of a trench. The semiconductor device can include a gate electrode provided via a gate insulating film in a first trench. The gate electrode penetrates the base region adjacent to the part of the source region. The gate electrode is extended from a part of the source region until a part of the drift region in a direction approximately parallel to a rear face of the drain layer. The semiconductor device can include a first resistive body layer provided via a first insulating film in at least one of second trenches provided from a surface to an inside of the drain layer. The semiconductor device can include a drain electrode connected to the drain layer. The semiconductor device can include a source electrode connected to the source region and the base region. The first resistive body layer is electrically connected to the source electrode.

Hereinafter, with reference to the drawings, embodiments are explained. In the explanation below, the same reference numeral is given to the same member, and, for the member once explained, the explanation thereof is suitably omitted.

### First Embodiment

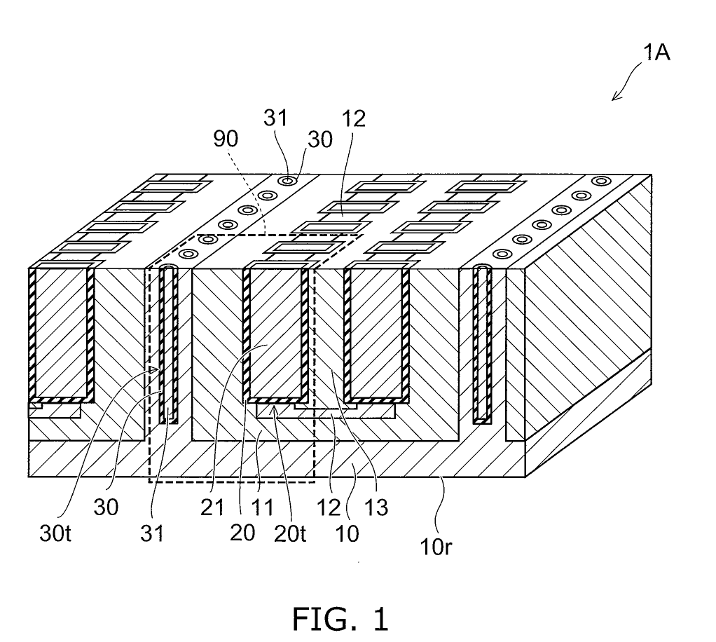

FIG. 1 is a perspective schematic view of the semiconductor device according to a first embodiment.

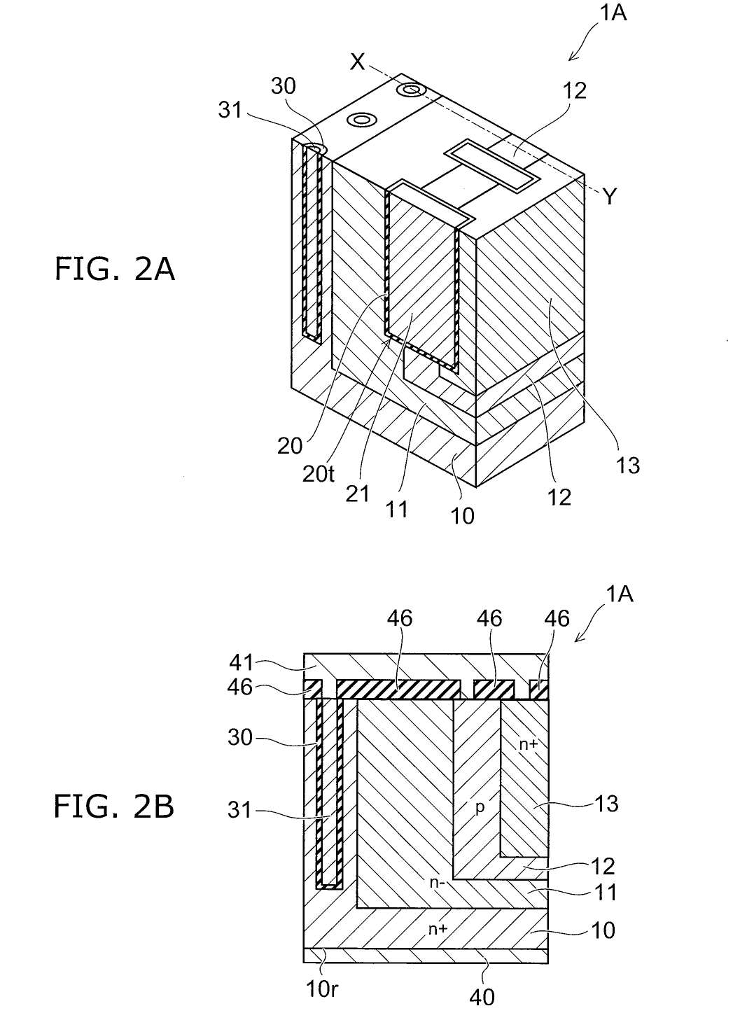

FIGS. 2A and 2B are schematic views of a part surrounded by a region 90 in FIG. 1. FIG. 2A is a perspective schematic view, and 2B is a X-Y cross-sectional view in 2A. In FIGS. 1 and 2A, a drain electrode 40 and a source electrode 41, which are to be described later, are not shown.

A semiconductor device 1A according to the first embodiment is a three-dimensional type MOSFET. The semiconductor device 1A has an n⁺-type drain layer 10. An n⁻-type drift region 11 is provided selectively from the surface to the inside of the drain layer 10. The drift region 11 is in the form of a trench. A p-type base region 12 is provided selectively from the surface to the inside of the drift region 11. The base region 12 is in the form of a trench. An n⁺-type source region 13 is provided selectively from the surface to the inside of the base region 12. The source region 13 is in the form of a trench.

In the semiconductor device 1A, a first trench 20t is formed in a direction approximately parallel to a rear face 10r of the drain layer 10. The first trench 20t penetrates the base region 12 adjacent to the part of the source region 13 from a part of the source region 13 to a part of the drift region 11. The lower edge of the first trench 20t is higher than the lower edge of the source region 13. A gate electrode 21 provided via the gate insulating film 20 is provided in the first trench 20t. The gate electrode is extended from a part of the source region 13 until a part of the drift region 11 in a direction approximately parallel to the rear face 10r of the drain layer 10.

In the semiconductor device 1A, at least one of second trenches 30t is provided from the surface to the inside of the drain layer 10. In the second trench 30t, a first resistive body layer 31 provided via the first insulating film 30 is provided.

In the semiconductor device 1A, a drain electrode 40 is connected to the drain layer 10. A source electrode 41 is connected to the source region 13 and the base region 12. An interlayer insulating film 46 is provided between the drain layer 10 and the source electrode 41, and between the drift region 11 and the source electrode 41. The interlayer insulating film 46 above the first resistive body layer 31 is opened, and the first resistive body layer 31 is electrically connected to the source electrode 41.

The major component of the drain layer 10, the drift region 11, the base region 12, and the source region 13 is, for example, silicon (Si). The material of the drain electrode 40 and the source electrode 41 is, for example, copper (Cu), aluminum (Al) or the like.

The material of the gate electrode 21 is, for example, polysilicon (poly-Si) doped with n-type impurities, metal or the like. The material of the gate insulating film 20 is, for example, silicon oxide (SiO₂).

The material of the first resistive body layer 31 is polysilicon (poly-Si) containing impurities. For example, the material of the first resistive body layer 31 is polysilicon (poly-Si) doped with n-type impurities. In addition, as the material of the first resistive body layer 31, a metal of high resistance or the like is acceptable. When the material of the first resistive body layer 31 is polysilicon, the doping quantity of the n-type impurities in the first resistive body layer 31 is appropriately adjusted and the specific resistance of the first resistive body layer 31 is set to be a prescribed value.

The first insulating film 30 is made of a dielectric material, and has at least one of layers. The material of the layer is, for example, any of silicon oxide (SiO₂), silicon nitride (Si₃N₄), alumina (Al₂O₃), hafnium oxide (HfO₂), aluminum hafnium oxide (HfAlₓO_{y}), yttrium oxide (Y₂O₃), hafnium yttrium oxide (HfYₓO_{y}) etc.

In the embodiment, the n-type (including n⁻-type, n⁺-type) may be called as a first conductivity type, and the p-type may be called as a second conductivity type. The impurities in the first conductivity type are, for example, phosphorous (P), arsenic (As), and the like. The impurities in the second conductivity type are, for example, boron (B), and the like.

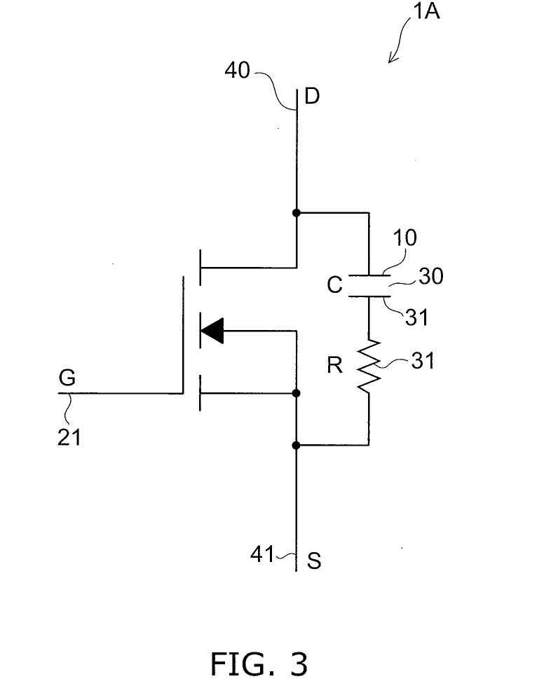

FIG. 3 is an equivalent circuit view of the semiconductor device according to the first embodiment.

The semiconductor device 1A includes a gate electrode (G) 21, a source electrode (S) 41 and a drain electrode (D) 40. The electric potential of the source electrode 41 is, for example, the ground potential, and the electric potential of the drain electrode 40 is, for example, a positive potential. When an electric potential not less than the threshold level is given to the gate electrode 21, the semiconductor device 1A is turned ON, and a current flows between the source electrode 41 and the drain electrode 40.

In the semiconductor device 1A, each of the source region 13, the base region 12, and the drift region 11 is extended in a direction approximately perpendicular to the rear face 10r of the drain layer 10. Furthermore, the trench type gate electrode 21 is provided. Accordingly, a channel region is provided in a direction approximately parallel to the rear face 10r of the drain layer 10, and a channel region is also formed in a direction approximately perpendicular to the rear face 10r of the drain layer 10. Consequently, the channel density is remarkably improved in the semiconductor device 1A. Consequently, an ON-resistance between the source electrode 41 and the drain electrode 40 is reduced.

In the semiconductor device 1A, the first resistive body layer 31 is connected to the source electrode 41. The first insulating film 30 is provided between the first resistive body layer 31 and the drain layer 10.

Accordingly, in the semiconductor device 1A, a resistance (R) and a capacitance (C) are added between the source electrode 41 and the drain electrode 40. The capacitance (C) is connected in series to the resistance (R). The resistance (R) is the resistance of the first resistive body layer 31, and the capacitance (C) is a capacitance generated by a condenser (first resistive body layer 31/first insulating film 30/drain layer 10).

That is, a snubber circuit is added to the semiconductor device 1A between the source electrode 41 and the drain electrode 40. Consequently, when the semiconductor device 1A is subjected to high-speed switching, the ringing of the voltage (Vds) between the source electrode 41 and the drain electrode 40 is suppressed. Consequently, noise generation is suppressed in the semiconductor device 1A.

The manufacturing course of the semiconductor device 1A is explained using a part of the semiconductor device 1A illustrated in FIGS. 2A and 2B.

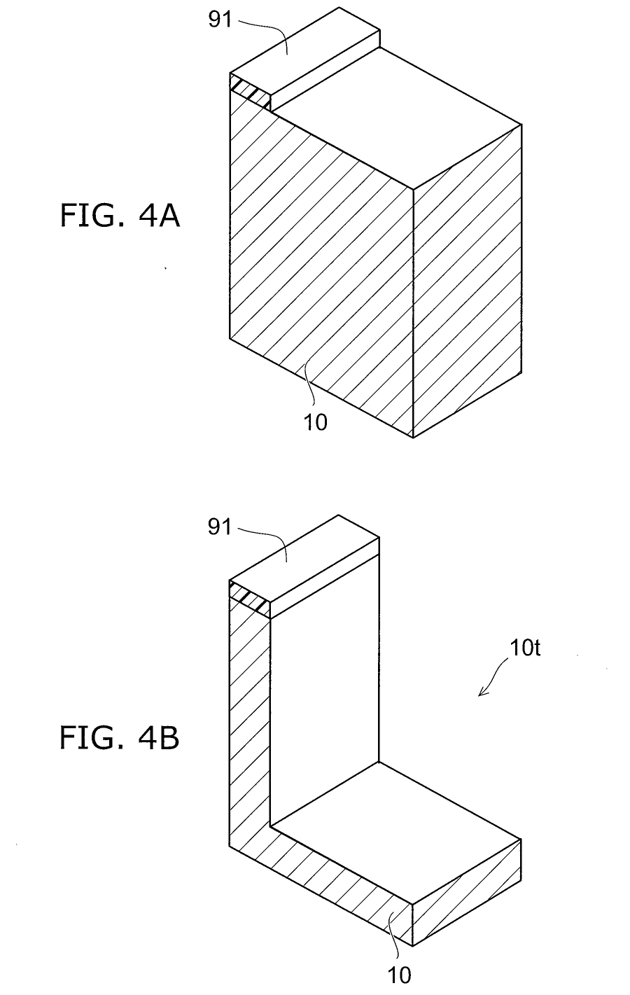

FIGS. 4A and 4B are perspective schematic views for explaining the manufacturing process of the semiconductor device according to the first embodiment. FIG. 4A is a perspective schematic view of a process of forming a mask on the surface of the semiconductor substrate, and FIG. 4B is a perspective schematic view of a process of performing an etching treatment on the semiconductor substrate.

First, as shown in FIG. 4A, the drain layer 10 is prepared. The drain layer 10 is a semiconductor substrate (semiconductor wafer) The impurity concentration in the drain layer 10 is, for example, not less than 1×10¹⁸ (atoms/cm³).

Subsequently, a mask 91 is formed selectively on the surface of the drain layer 10. The material of the mask 91 is, for example, resist, silicon oxide (SiO₂) or the like.

Next, as shown in FIG. 4B, a selective etching treatment is given to the drain layer 10 opened from the mask 91. Consequently, a trench 10t is formed from the surface to the inside of the drain layer 10.

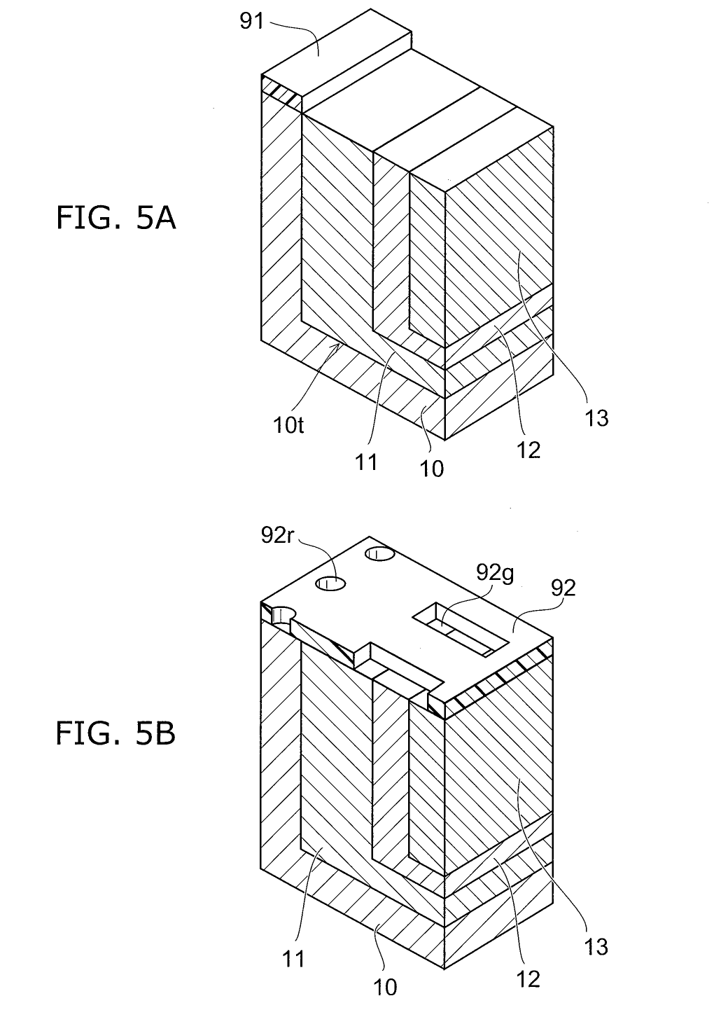

FIGS. 5A and 5B are perspective schematic views for explaining the manufacturing process of the semiconductor device according to the first embodiment. 5A is a perspective schematic view of a process of forming an epitaxial layer, and 5B is a perspective schematic view of a process of forming a mask.

As shown in FIG. 5A, in the trench 10t, by an epitaxial growth method, an n-type drift region 11 is formed. The impurity concentration in the drift region 11 is, for example, 1×10¹⁶ (atoms/cm³) to 1×10¹⁷ (atoms/cm³). Consequently, from the surface to the inside of the drain layer 10, the drift region 11 is formed.

The drift region 11 is not completely embedded into the trench 10t. For example, the growth of the drift region 11 is interrupted on the way. Consequently, the trench 10t remains (not shown) in the drift region 11. Subsequently, by an epitaxial growth method, a p-type base region 12 is formed in the trench 10t left in the drift region 11. Consequently, the base region 12 is formed from the surface to the inside of the drift region 11.

Furthermore, the growth of the base region 12 is interrupted in the middle. And, by an epitaxial method, an n⁺-type source region 13 is formed in the trench 10t left in the base region 12. Consequently, the source region 13 is formed selectively from the surface to the inside of the base region 12.

After that, the surfaces of the drift region 11, the base region 12 and the source region 13 are appropriately subjected to CMP (Chemical Mechanical Polishing) (not shown). Consequently, the surfaces of the drift region 11, base region 12 and the source region 13 are made flat. The mask 91 is removed by etching, CMP polishing or the like.

Next, as shown in FIG. 5B, a mask 92 is formed selectively on the surface of the drain layer 10, the drift region 11, the base region 12 and the source region 13. On the mask 92, an opening 92g for forming the gate electrode 21, and an opening 92r for forming the first resistive body layer 31 are provided selectively. The material of the mask 92 is, for example, resist, silicon oxide (SiO₂) or the like.

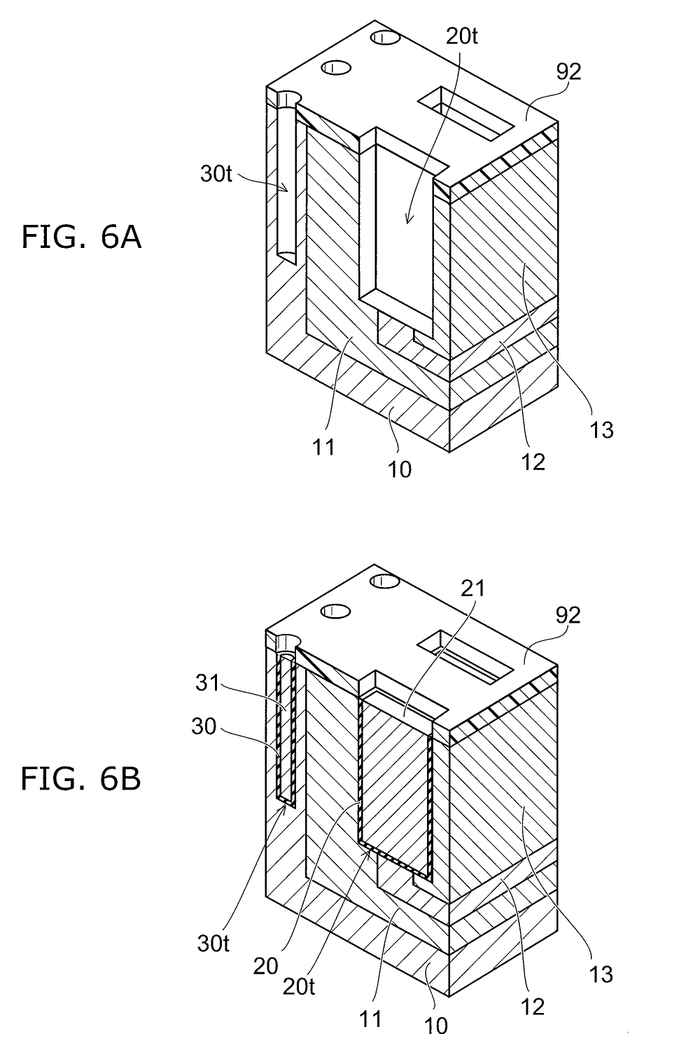

FIGS. 6A and 6B are perspective schematic views for explaining the manufacturing process of the semiconductor device according to the first embodiment. FIG. 6A is a perspective schematic view of a process of giving an etching treatment to the semiconductor substrate, and FIG. 6B is a perspective schematic view of a process of forming the gate electrode and the first resistive body layer.

Next, as shown in FIG. 6A, the drift region 11, the base region 12, and the source region 13 opened from the mask 92 via the opening 92g are subjected to a selective etching treatment. Furthermore, the drain layer 10 opened from the mask 92 via the opening 92r is subjected to a selective etching treatment.

By the etching treatment, the first trench 20t is formed in a part of each of the drift region 11, the base region 12 and the source region 13, and the second trench 30t is formed in the drain layer 10. Subsequently, the inside of the first trench 20t and the inside of the second trench 30t are exposed to an oxidizing atmosphere under high temperatures.

Consequently, as shown in FIG. 6B, the gate insulating film 20 is formed on the side face and the bottom face of the first trench 20t. Furthermore, the first insulating film 30 is formed on the side face and the bottom face of the second trench 30t. In the example, the material of the gate insulating film 20 and the first insulating film 30 is silicon oxide.

Subsequently, in the first trench 20t, the gate electrode 21 is formed by CVD (Chemical Vapor Deposition) via the gate insulating film 20. Furthermore, in the second trench 30t, the first resistive body layer 31 is formed by CVD via the first insulating film 30.

Consequently, the trench-shaped gate electrode 21 is formed selectively from the surface to the inside of the base region 12, from the surface to the inside of a part of the source region 13 adjacent to the base region 12, and from the surface to the inside of a part of the drift region 11 on the side opposite to the part of the source region 13. Furthermore, the first resistive body layer 31 is formed from the surface to the inside of the drain layer 10. A lower edge of the resistive body layer 31 and a lower edge of the gate electrode 21 are the same in height from the rear face of the drain layer 10. The first insulating film 30 is provided between the first resistive body layer 31 and the drain layer 10.

The material of the gate electrode 21 and the first resistive body layer 31 is, for example, polysilicon. When the material of the first resistive body layer 31 is polysilicon, the doping quantity of n-type impurities in the first resistive body layer 31 is appropriately adjusted, and the specific resistance of the first resistive body layer 31 is set to be a prescribed value. After forming the gate electrode 21 and the first resistive body layer 31, the mask 92 is removed.

Meanwhile, the embodiment includes both an embodiment of manufacturing a process of forming the gate insulating film 20 and the gate electrode 21 after forming the first trench 20t, and a process of forming the first insulating film 30 and the first resistive body layer 31 after forming the second trench 30t in the same process, and an embodiment in which respective processes are shifted.

For example, the mask 92 for manufacturing the first trench 20t exclusively and the mask 92 for manufacturing the second trench 30t exclusively are prepared. And, the first trench 20t is formed previously, and, after forming the gate electrode 21 in the first trench 20t via the gate insulating film 20, the second trench 30t is formed, and the first resistive body layer 31 is formed in the second trench 30t via the first insulating film 30. Alternatively, on the contrary, it is also possible to form the second trench 30t, and, after forming the first resistive body layer 31 in the second trench 30t via the first insulating film 30, to form the first trench 20t, and to form the gate electrode 21 in the first trench 20t via the gate insulating film 20.

Such manufacturing course can set the material of the gate insulating film 20 and the material of the first insulating film 30 to be different. Or, the material of the first resistive body layer 31 and the material of the material of the gate electrode 21 can be set to be different. Furthermore, the depth of the second trench 30t and the depth of the first trench 20t can be set to be different.

After this, as shown in FIGS. 1 and 2, the drain electrode 40 is connected to the drain layer 10. The source electrode 41 is connected to the source region 13, the base region 12 and the first resistive body layer 31. The interlayer insulating film 46 is provided between the source electrode 41, and the drain layer 10, the drift region 11, the base region 12 and the source region 13. By such manufacturing course, the semiconductor device 1A is formed.

Next, the effect of the semiconductor device 1A is explained in detail. Before explaining the effect of the semiconductor device 1A, a semiconductor device 500 according to a reference example is explained.

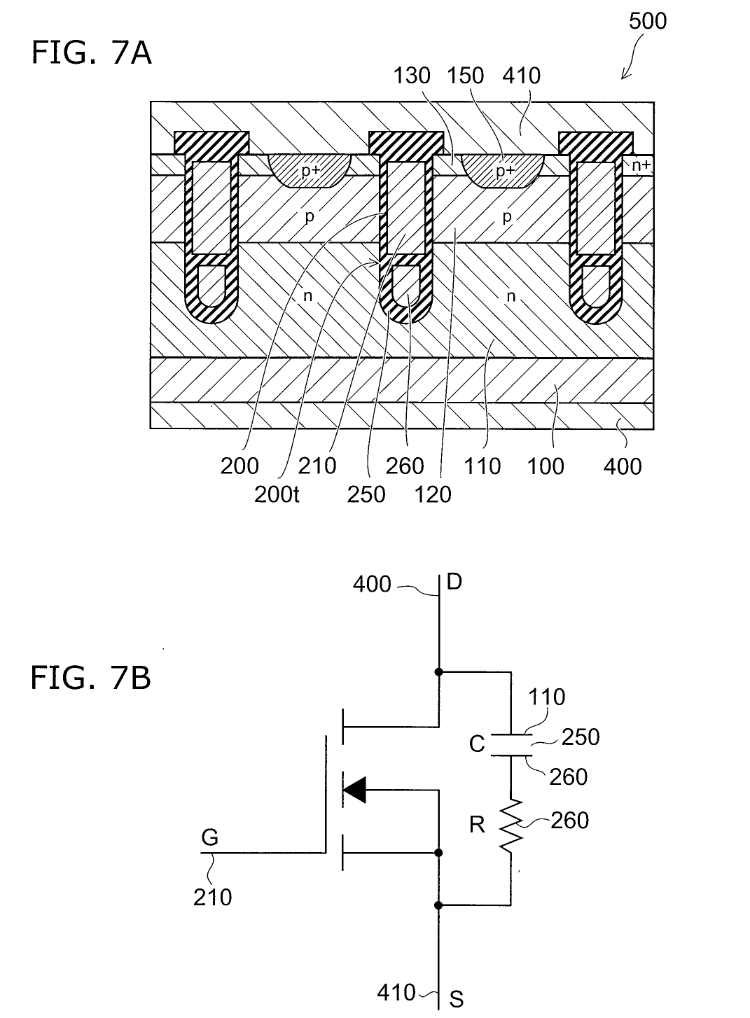

FIGS. 7A and 7B are schematic views of the semiconductor device according to the reference example. 7A is a cross-sectional schematic view, and 7B is an equivalent circuit view.

The semiconductor device 500 shown in FIG. 7A is an n-channel type MOSFET of a trench gate structure. The semiconductor device 500 includes an upper/lower electrode structure.

In the semiconductor device 500, on an n⁺-type drain layer 100, an n⁻-type drift region 110 is provided. On the drift region 110, a p-type base region 120 is provided. On the surface of the base region 120, an n⁺-type source region 130, and a p⁺-type carrier extraction region 150 is provided.

In the semiconductor device 500, a trench 200t is provided from the source region 130, passing through the base region 120 and reaching the drift region 110. In the trench 200t, a gate electrode 210 is provided via the gate insulating film 200. Furthermore, on the lower side of the gate electrode 210, in the trench 200t, a field plate electrode 260 is provided via a field plate insulating film 250.

A drain electrode 400 is connected to the drain layer 100. A source electrode 410 is connected to the source region 130 and the carrier extraction region 150. The field plate electrode 260 is electrically connected to the source electrode 410.

An equivalent circuit of the semiconductor device 500 is shown in FIG. 7B. In FIG. 7B, the gate electrode (G) 210, the source electrode (S) 410 and the drain electrode (D) 400 are shown.

The electric potential of the source electrode 410 is, for example, the ground potential, and the electric potential of the drain electrode 400 is, for example, a positive potential. When an electric potential not less than the threshold level is given to the gate electrode 210, the semiconductor device 500 is turned ON, and a current flows between the source electrode 410 and the drain electrode 400.

In the semiconductor device 500, since the field plate electrode 260 is provided on the lower side of the gate electrode 210, the drift region 110 is easily depleted, and the impurity concentration in the drift region 110 can be raised. Consequently, in the semiconductor device 500, high breakdown voltage and low ion resistance are realized.

Moreover, since the field plate electrode 260 has a prescribed resistance, a prescribed resistance (R) exists between the source electrode 410 and the drain electrode 400. Furthermore, the field plate insulating film 250 exists between the field plate electrode 260 and the drain electrode 400, and thus, a prescribed capacitance (C) exists between the source electrode 410 and the drain electrode 400.

That is, between the source electrode 410 and the drain electrode 400, a resistance (R) and a capacitance (C) connected in series to the resistance (R) are added. Accordingly, in the semiconductor device 500, a snubber circuit is formed substantially between the source electrode 410 and the drain electrode 400.

But, the thickness of the field plate insulating film 250 is necessary to be a certain thickness having a dielectric strength voltage against the voltage applied between the field plate electrode 260 and the drift region 110, and is necessary to be a certain thickness allowing a depletion layer to extend sufficiently from the field plate insulating film 250 toward the drift region 110. That is, in order to realize the semiconductor device 500 characteristics, the thickness of the field plate insulating film 250 must be determined from both aspects of the breakdown voltage and the depletion.

On the contrary, in the semiconductor device 1A, with regard to the thickness of the first insulating film 30, a thickness having a dielectric strength voltage against the voltage applied between the drain layer 10 and the first resistive body layer 31 is sufficient. Accordingly, in the semiconductor device 1A, the degree of freedom of designing the first insulating film 30 increases, as compared with the semiconductor device 500.

Moreover, in the semiconductor device according to the embodiment, the resistance and the capacitance of the snubber circuit may easily be changed.

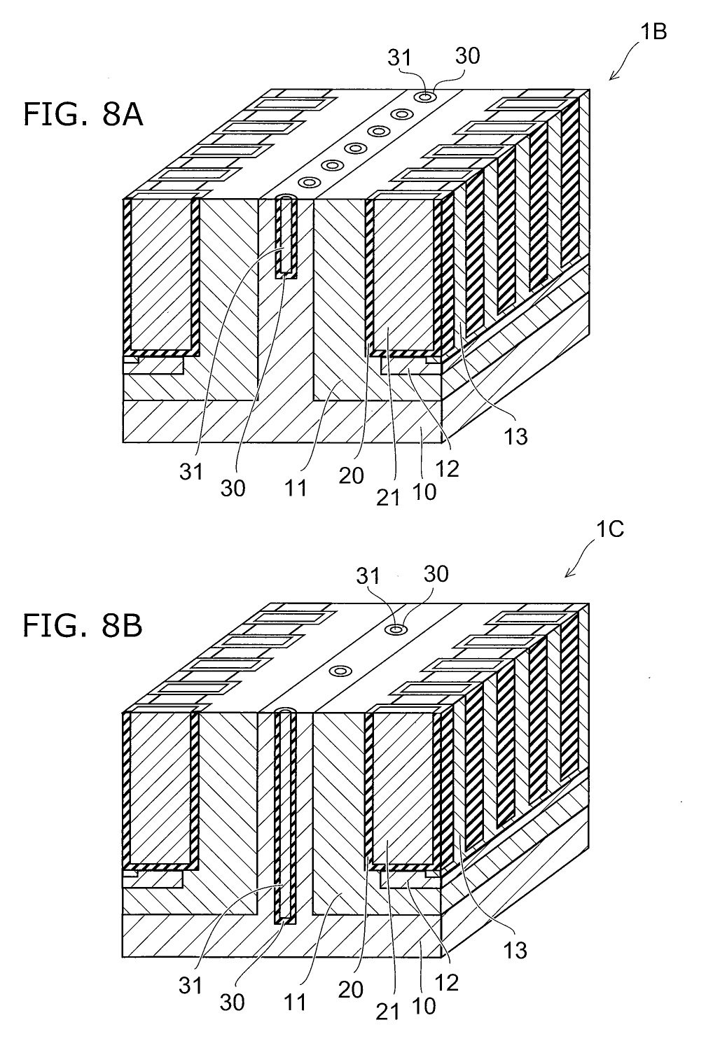

FIGS. 8A and 8B are perspective schematic views for explaining a first modified example of the semiconductor device according to the first embodiment.

For example, as compared with the configuration of the semiconductor device 1A shown in FIG. 1, when such design is intended that the snubber circuit is to have a larger capacitance and a smaller resistance, an approach below is mentioned.

In the semiconductor device 1B shown in FIG. 8A, as compared with the semiconductor device 1A, densities of the first insulating film 30 and the first resistive body layer 31 are higher, and depths of the first insulating film 30 and the first resistive body layer 31 are shallower. That is, a distance between the rear face of the drain layer 10 and a lower edge of the resistive body layer 31 is longer than a distance between the rear face of the drain layer 10 and a lower edge of the gate electrode 21. Consequently, in the semiconductor device 1B, the capacitance of the snubber circuit is larger as compared with the semiconductor device 1A, and the resistance is smaller.

Moreover, as compared with the configuration of the semiconductor device 1A shown in FIG. 1, when the design is required such that the snubber circuit has a smaller capacitance and a larger resistance, an approach below is mentioned.

For example, in the semiconductor device 1C shown in FIG. 8B, as compared with FIG. 1, densities of the first insulating film 30 and the first resistive body layer 31 are lower, and depths of the first insulating film 30 and the first resistive body layer 31 are deeper. That is, a distance between the rear face of the drain layer 10 and a lower edge of the resistive body layer 31 is shorter than a distance between the rear face of the drain layer 10 and a lower edge of the gate electrode 21. Consequently, in the semiconductor device 1C, as compared with the semiconductor device 1A, the capacitance of the snubber circuit is smaller, and the resistance is larger.

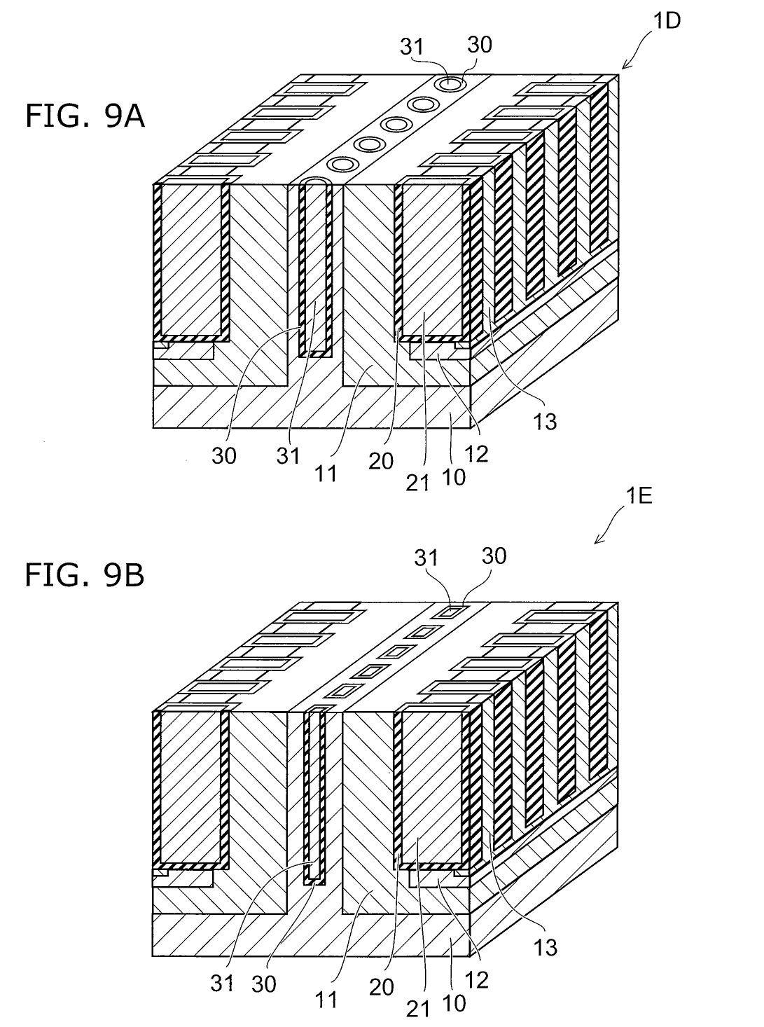

FIGS. 9A and 9B are perspective schematic views for explaining a second modified example of the semiconductor device according to the first embodiment. In FIGS. 9A and 9B, appearances seen from the direction perpendicular to the surface of the drain layer 10 are shown.

In a semiconductor device 1D shown in FIG. 9A, the area of the first resistive body layer 31 is larger as compared with the semiconductor device 1A. Consequently, the contact area of the first resistive body layer 31 and the drain layer 10 increases, and the capacitance of the snubber circuit is larger as compared with the semiconductor device 1A.

Or, contrary to the semiconductor device 1D, the area of the first resistive body layer 31 may be made smaller as compared with the semiconductor device 1A. Consequently, the contact area of the first resistive body layer 31 and the drain layer 10 decreases, and the capacitance of the snubber circuit is smaller as compared with the semiconductor device 1A.

In a semiconductor device 1E shown in FIG. 9B, the shape of the first resistive body layer 31 cut parallel to the rear face 10r of the drain layer 10 is set to be a polygon such as a tetragon. Even in such configuration, the contact area of the first resistive body layer 31 and the drain layer 10 increases, and the capacitance of the snubber circuit increases as compared with the semiconductor device 1A. Consequently, by the second modified example, too, the capacitance of the snubber circuit can easily be changed.

Moreover, when the material of the first resistive body layer 31 is polysilicon, by adjusting the concentration of impurities contained in the polysilicon, the specific resistance of the first resistive body layer 31 itself may also be adjusted.

In addition, since the first insulating film 30 and the first resistive body layer 31 have a structure exposed on the surface of the drain layer 10, after forming the gate electrode 21, design changes of the first insulating film 30 and the first resistive body layer 31 are also possible. In the semiconductor device 500, since the gate electrode 210 is formed on the field plate electrode 260, the design change after forming the gate electrode is not possible.

As described above, in the semiconductor device according to the first embodiment, the ON-resistance is low and the generation of noise is suppressed, and the degree of freedom of designing the capacitance and resistance of the snubber circuit increases.

### Second Embodiment

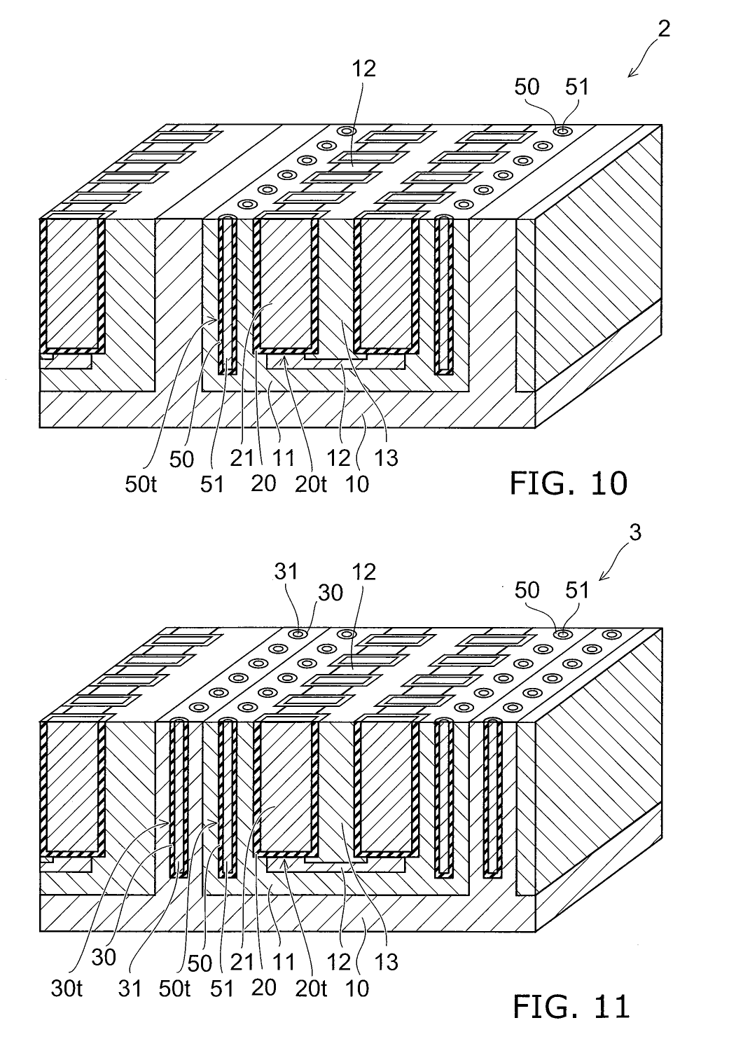

FIG. 10 is a perspective schematic view of the semiconductor device according to a second embodiment.

In the semiconductor device 2 according to the second embodiment, at least one of third trenches 50t is provided from the surface to the inside of the drift region 11. In the third trench 50t, a second resistive body layer 51 is provided via a second insulating film 50. And, the second resistive body layer 51 is electrically connected to the source electrode 41.

The material of the second resistive body layer 51 is the same as the material of the first resistive body layer 31. When the material of the second resistive body layer 51 is polysilicon, the doping quantity of n-type impurities in the second resistive body layer 51 is appropriately adjusted, and the specific resistance of the second resistive body layer 51 is set to be a prescribed value. The material of the second insulating film 50 is the same as the material of the first insulating film 30.

In the semiconductor device 2, a resistance (R) and a capacitance (C), connected to the resistance (R) in series, are added between the source electrode 41 and the drain electrode 40. The resistance (R) is the resistance of the second resistive body layer 51, and the capacitance (C) is a capacitance generated by the condenser (second resistive body layer 51/second insulating film 50/drain layer 10).

That is, between the source electrode 41 and the drain electrode 40, a snubber circuit is added to the semiconductor device 2. Consequently, the ringing of the voltage (Vds) between the source electrode 41 and the drain electrode 40 is suppressed when the semiconductor device 2 is subjected to high-speed switching. Consequently, in the semiconductor device 2, noise generation is suppressed. Moreover, the degree of freedom of designing the second insulating film 50 and the second resistive body layer 51 is also high as is the case for the first insulating film 30 and the first resistive body layer 31.

As described above, in the semiconductor device according to the second embodiment, an ON-resistance is low and the noise generation is suppressed, and the degree of freedom of designing the capacitance and resistance of the snubber circuit increases.

### Third Embodiment

FIG. 11 is a perspective schematic view of the semiconductor device according to a third embodiment.

A semiconductor device 3 according to the third embodiment has a composite configuration of the semiconductor device according to the first embodiment and the semiconductor device according to the second embodiment.

In the semiconductor device 3 according to the third embodiment, at least one of second trenches 30t is provided from the surface to the inside of the drain layer 10. In the second trench 30t, the first resistive body layer 31 provided via the first insulating film 30 is provided. Furthermore, at least one of third trenches 50t is provided from the surface to the inside of the drift region 11. In the third trench 50t, the second resistive body layer 51 is provided via the second insulating film 50. And, the first resistive body layer 31 and the second resistive body layer 51 are electrically connected to the source electrode 41. Such configuration is also included in the embodiment.

Hereinabove, exemplary embodiments are described with reference to specific examples. However, the embodiments are not limited to these specific examples. That is, any of the specific examples to which one skilled in the art has appropriately added a design change is included in the scope of the embodiment to the extent that the purport of the invention is included. Respective elements and the arrangement, material, condition, shape, size etc. thereof included in the aforementioned embodiments are not limited to exemplified ones, but can be changed appropriately. In the embodiments, examples of the n-channel type MOSFET was explained, but a p-channel type MOSFET may also be acceptable.

Moreover, respective elements included in respective embodiments can be combined within the extent of technical feasibility and ones combined these are included in the scope of the embodiment to the extent that the purport of the embodiment is included. In addition, one skilled in the art can conceive various changed examples and modified examples within the idea of the embodiment, and these changed examples and modified examples are also understood to be within the scope of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a drain layer of a first conductivity type;
a drift region of the first conductivity type provided from a surface to an inside of the drain layer, the drift region being in the form of a trench;
a base region of a second conductivity type provided from a surface to an inside of the drift region, the base region being in the form of a trench;
a source region of the first conductivity type provided in a trench form from a surface to an inside of the base region, the source region being in the form of a trench;
a gate electrode provided via a gate insulating film in a first trench, the gate electrode penetrating the base region adjacent to the part of the source region, the gate electrode being extended from a part of the source region until a part of the drift region in a direction approximately parallel to a rear face of the drain layer;
a first resistive body layer provided via a first insulating film in at least one of second trenches provided from a surface to an inside of the drain layer;
a drain electrode connected to the drain layer; and
a source electrode connected to the source region and the base region, wherein the first resistive body layer is electrically connected to the source electrode.

2. The device according to claim 1, wherein a material of the first resistive body layer is polysilicon containing impurities.

3. The device according to claim 1, wherein the first insulating film has at least one of first layers, and a material of the at least one of first layers is any one of silicon oxide, silicon nitride, alumina, hafnium oxide, aluminum hafnium oxide, yttrium oxide and hafnium yttrium oxide.

4. The device according to claim 1, further comprising: a second resistive body layer provided via a second insulating film in at least one of third trenches provided from a surface to an inside of the drift region.

5. The device according to claim 4, wherein a material of the second resistive body layer is polysilicon containing impurities.

6. The device according to claim 4, wherein the second insulating film has at least one of second layers, and a material of the at least one of second layers is any one of silicon oxide, silicon nitride, alumina, hafnium oxide, aluminum hafnium oxide, yttrium oxide and hafnium yttrium oxide.

7. The device according to claim 1, wherein a lower edge of the first resistive body layer and a lower edge of the gate electrode are the same in height from the rear face of the drain layer.

8. The device according to claim 1, wherein a distance between the rear face of the drain layer and a lower edge of the first resistive body layer is longer than a distance between the rear face of the drain layer and a lower edge of the gate electrode.

9. The device according to claim 1, wherein a distance between the rear face of the drain layer and a lower edge of the first resistive body layer is shorter than a distance between the rear face of the drain layer and a lower edge of the gate electrode.

10. The device according to claim 1, wherein a shape of the first resistive body layer cut in parallel to the rear face of the drain layer is circular.

11. The device according to claim 1, wherein a shape of the first resistive body layer cut in parallel to the rear face of the drain layer is polygonal.

12. A semiconductor device comprising:
a drain layer of a first conductivity type;
a drift region of the first conductivity type provided from a surface to an inside of the drain layer, the drift region being in the form of a trench;
a base region of a second conductivity type provided from a surface to an inside of the drift region, the base region being in the form of a trench;
a source region of the first conductivity type provided from a surface to an inside of the base region, the source region being in the form of a trench;
a gate electrode provided via a gate insulating film in a first trench penetrating the base region adjacent to the part of the source region, the gate electrode being extended from a part of the source region until a part of the drift region in a direction approximately parallel to a rear face of the drain layer;
a second resistive body layer provided via a second insulating film in at least one of third trenches provided from a surface to an inside of the drift region;
a drain electrode connected to the drain layer; and
a source electrode connected to the source region and the base region, wherein the second resistive body layer is electrically connected to the source electrode.

13. The device according to claim 12, wherein a material of the second resistive body layer is polysilicon containing impurities.

14. The device according to claim 12, wherein the second insulating film has at least one of layers, and a material of the at least one of layers is any one of silicon oxide, silicon nitride, alumina, hafnium oxide, aluminum hafnium oxide, yttrium oxide and hafnium yttrium oxide.

15. The device according to claim 12, wherein a shape of the second resistive body layer cut in parallel to the rear face of the drain layer is circular.
